(19) United States
(12) Patent Application Publication
(10) Pub. No.: US 2025/0338678 A1
(43) Pub. Date: Oct. 30, 2025

(54) WAVELENGTH CONVERTER FOR LUMINESCENCE THERMOMETRY

(71) Applicant: LUMILEDS LLC, San Jose, CA (US)

(72) Inventors: Peter Josef Schmidt, Aachen (DE); Ronald Mikkenie, Simpelveld (NL); Oliver Steigelmann, Aachen (DE)

(73) Assignee: Lumileds LLC, San Jose, CA (US)

(21) Appl. No.: 18/651,076

(22) Filed: Apr. 30, 2024

(51) Int. Cl. H01L 33/50; H01L 25/16

(52) U.S. Cl. CPC H10H 20/8512; H01L 25/167

(57) ABSTRACT

A wavelength converter material doped with one or more rare earth elements may provide improved temperature sensing precision and/or improved mechanical stability due to reduced structural anisotropy. The converter material may be powder phosphor or ceramic phosphor. The converter material may comprise GdAlO₃:Cr in addition to the one or more rare earth elements.

### FIELD OF THE INVENTION

The invention relates generally to wavelength converters, particularly doped wavelength converters for luminescence thermometry.

### BACKGROUND

The general illumination industry has witnessed remarkable advancements in technology, with one breakthrough being the invention of Light-Emitting Diodes (LEDs). This innovation has transformed the way we perceive and experience general illumination, offering improved efficiency, durability, and versatility. Developed as a response to the limitations of traditional light source, LEDs have become a staple feature in areas like modern grounded vehicles, providing enhanced safety, aesthetics, and functionality.

One area that LEDs can be used in is luminescence thermometry. Luminescence thermometry is a way of remote sensing that relies on the luminescence characteristics of converter material to measure temperature. Luminescence thermometers are applied in environments that prohibit the use of metal based thermometers such as RF or microwave heated furnaces used in the semiconductor industry.

Certain phosphors are particularly suited for luminescence thermometry. For example, a polycrystalline ceramic is especially useful for luminescence based thermal sensing applications because of high thermal conductivity and luminescence conversion efficiency. While a high thermal conductivity improves the sensor response time, a high luminescence conversion efficiency improves the sensor precision because of a longer decay trace above the measurement noise floor. For example, GdAlO3:Cr can be shaped and sintered into polycrystalline ceramics and can be applied as a sensing component in a luminescence decay based thermometer arrangement. While the strong orthorhombic distortion of the perovskite structure motif in compounds like GdAlO3:Cr is advantageous for the material's absorption cross section, the absorption of pump light in the 400-440 nm range is still rather low if compared to, e.g., absorption of luminescent materials showing parity allowed transitions. From an application point of view, the mechanical stability of a polycrystalline ceramic may also be important to allow machining operations like dicing without chipping or to provide a high thermal shock resistance. Polycrystalline ceramics made of orthorhombic GdAlO3:Cr can show a reduced mechanical stability compared to, e.g., a cubic perovskite. This may most likely be caused by randomly orientated ceramic grains and an anisotropic thermal expansion behaviour that may lead to crack formation or ceramic disintegration under very fast thermal cycling or thermal shock. Such conditions may appear during thermal sensing operation in, e.g., flames.

Another issue that may come from GdAlO₃:Cr as a thermographic sensor material is the paramagnetic coupling between Cr³⁺ and Gd³⁺ ions that may lead to fluctuations of luminescence lifetime at higher temperature, depending on the thermal history and/or storing conditions of the sensor material. Diamagnetic dilution of the Gd³⁺ sublattice with cations, e.g., La³⁺ and/or Lu³⁺, may reduce magnetic interactions and lowers luminescence lifetime fluctuations of the Cr³⁺ centers under thermal cycling of the sensor material.

### SUMMARY

Embodiments of the invention include solve the issue mentioned above by providing converter material doped with one or more rare earth elements. For example, ceramic converter materials based on Cr³⁺ doped rare earth aluminates may show not only improved temperature sensing precision due to a combination of longer decay traces above noise background, steeper decay vs. T calibration curves and improved luminescence lifetime consistency, but also a reduced structural anisotropy by solid solution formation.

These and other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1 shows a schematic cross-sectional view of an example pcLED.

FIGS. 2A and 2B show, respectively, cross-sectional and top schematic views of an array of pcLEDs. FIG. 2C shows a schematic top view of an LED wafer from which LED arrays such as those illustrated in FIGS. 2A and 2B may be formed.

FIG. 3A shows a schematic top view of an electronics board on which an array of pcLEDs may be mounted, and FIG. 3B similarly shows an array of pcLEDs mounted on the electronic board of FIG. 3A.

FIG. 4A shows a schematic cross-sectional view of an array of pcLEDs arranged with respect to waveguides and a projection lens. FIG. 4B shows an arrangement similar to that of FIG. 4A, without the waveguides.

FIG. 5 schematically illustrates an example camera flash system.

FIG. 6 shows lattice constants of comparative example preparation A and example preparations 1-3.

FIG. 7 shows room temperature emission spectra of comparative example preparation A and example preparations 1-3.

FIG. 8 shows room temperature excitation spectra for comparative example preparation A and example preparations 1-3.

FIG. 9 shows single-exponentially fitted decay times as a function of temperature for comparative example preparation A and example preparations 1-3.

FIG. 10 shows the room emission spectrum of example preparation 9.

FIG. 11 shows the mono-exponentially fitted decay time of example preparation 9 as function of the converter temperature.

FIG. 12 shows a normalized detector signal at room temperature as function of the ceramic thickness for a given setup.

FIG. 13 shows the corresponding signal decay traces for the given setup of FIG. 12.

FIG. 14 shows the spectral power distribution of example preparation 8 emission.

FIG. 15 shows the spectral power distribution of example preparation 7 emission.

FIG. 16 shows monoexponentially fitted decay time versus temperature plots for comparative example preparation B and example preparations 6-7.

FIG. 17 shows a comparison of the maximal detector signals versus temperature for comparative example preparation B and example preparations 6-7.

FIG. 18 illustrates a device for temperature sensing comprising a light emitting device exciting a converter structure which then emits light into a photodetector.

FIG. 19 illustrates a device for temperature sensing comprising a light emitting device exciting multiple converter structure which then emit light into multiple photodetectors.

FIG. 20 illustrates a converter structure sandwiched between two substrates.

FIG. 21 illustrates a converter structure disposed on a single substrate.

FIG. 22 illustrates a microscope image of example 8.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention. This description will clearly enable one skilled in the art to make and use the invention, and describes several embodiments, adaptations, variations, alternatives and uses of the invention.

As used in this specification and the appended claims, the singular forms “a,” “an,” and “the” include plural referents unless the context clearly indicates otherwise. Also, the term “parallel” is intended to mean “substantially parallel” and to encompass minor deviations from parallel geometries. The term “vertical” refers to a direction parallel to the force of the earth's gravity. The term “horizontal” refers to a direction perpendicular to “vertical.” The term “on” means to be disposed to overlap (e.g., vertically) and/or to be directly in contact with.

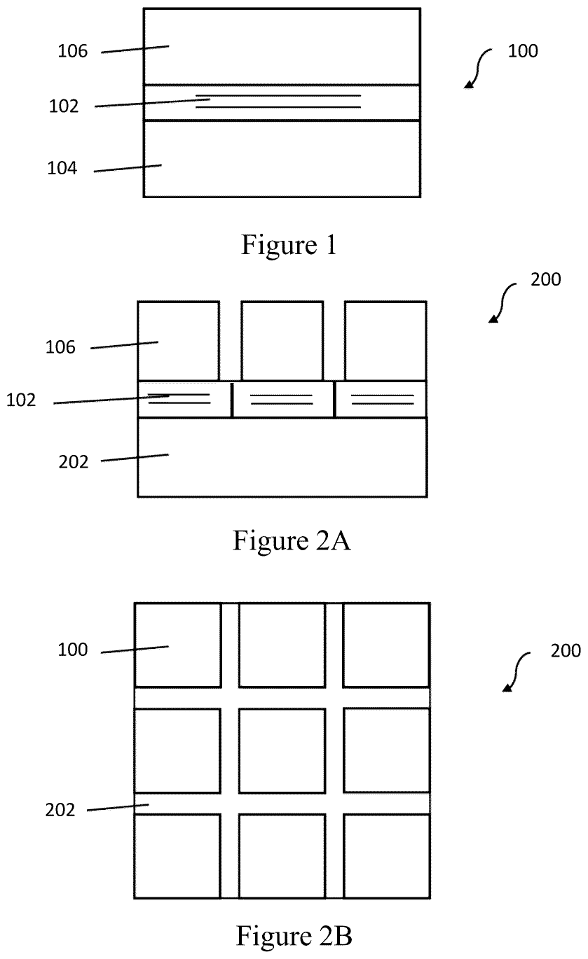

FIG. 1 shows an example of an individual pcLED 100 comprising a light emitting semiconductor diode (LED) structure 102 disposed on a substrate 104, and a phosphor layer 106 (also referred to herein as a wavelength converting structure) disposed on the LED. Light emitting semiconductor diode structure 102 typically comprises an active region disposed between n-type and p-type layers. Application of a suitable forward bias across the diode structure results in emission of light from the active region. The wavelength of the emitted light is determined by the composition and structure of the active region.

The LED may be, for example, a III-Nitride LED that emits ultraviolet, blue, green, or red light. LEDs formed from any other suitable material system and that emit any other suitable wavelength of light may also be used. Other suitable material systems may include, for example, III-Phosphide materials, III-Arsenide materials, and II-VI materials.

Any suitable phosphor materials may be used, depending on the desired optical output and color specifications from the pcLED. Phosphor layers may for example comprise phosphor particles dispersed in or bound to each other with a binder material, or be or comprise a sintered ceramic phosphor plate.

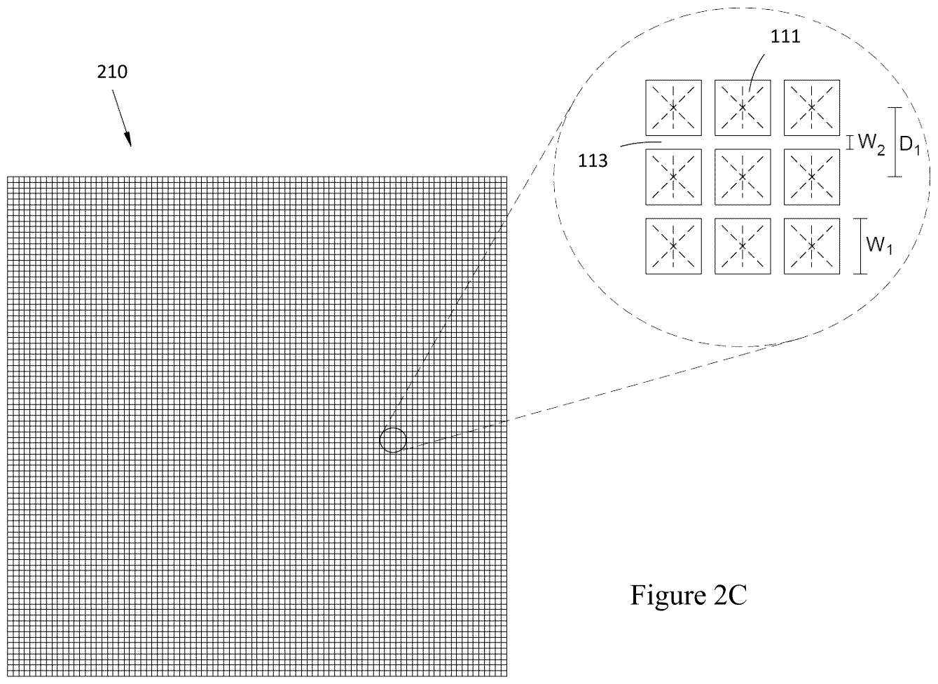

FIGS. 2A-2B show, respectively, cross-sectional and top views of an array 200 of pcLEDs 100 including phosphor layers 106 disposed on a substrate 202. Such an array may include any suitable number of pcLEDs arranged in any suitable manner. In the illustrated example the array is depicted as formed monolithically on a shared substrate, but alternatively an array of pcLEDs may be formed from individual mechanically separate pcLEDs arranged on a substrate. Substrate 202 may optionally comprise CMOS circuitry for driving the LED and may be formed from any suitable materials.

Although FIGS. 2A-2B show a three-by-three array of nine pcLEDs, such arrays may include for example tens, hundreds, or thousands of LEDs. Individual LEDs may have widths (e.g., side lengths) in the plane of the array of, for example, less than or equal to 1 millimeter (mm), less than or equal to 500 microns, less than or equal to 100 microns, or less than or equal to 50 microns. LEDs in such an array may be spaced apart from each other by streets or lanes having a width in the plane of the array of, for example, hundreds of microns, less than or equal to 100 microns, less than or equal to 50 microns, less than or equal to 10 microns, or less than or equal to 5 microns.

FIG. 2C shows a schematic top view of a portion of an LED wafer 210 from which LED arrays such as those illustrated in FIGS. 2A and 2B may be formed. FIG. 2C also shows an enlarged 3×3 portion of the wafer. In the example wafer individual LEDs or pcLEDs 111 having side lengths (e.g., widths) of W1 are arranged as a square matrix with neighboring LEDs or pcLEDs having a center-to-center distances D1 and separated by lanes 113 having a width W2. W1 may be, for example, less than or equal to 1 millimeter (mm), less than or equal to 500 microns, less than or equal to 100 microns, less than or equal to 50 microns, or less than or equal to 10 microns. W2 may be, for example, hundreds of microns, less than or equal to 100 microns, less than or equal to 50 microns, less than or equal to 10 microns, or less than or equal to 5 microns. D1=W1+W2.

An array may be formed, for example, by dicing wafer 210 into individual LEDs or pcLEDs and arranging the dice on a substrate. Alternatively, an array may be formed from the entire wafer 210, or by dividing wafer 210 into smaller arrays of LEDs or pcLEDs.

LEDs having dimensions in the plane of the array (e.g., side lengths) of less than or equal to about 50 microns are typically referred to as microLEDs, and an array of such microLEDs may be referred to as a microLED array.

Although the illustrated examples show rectangular LEDs or pcLEDs arranged in a symmetric matrix, the LEDs or pcLEDs and the array may have any suitable shape or arrangement and need not all be of the same shape or size. For example, LEDs or pcLEDs located in central portions of an array may be larger than those located in peripheral portions of the array. Alternatively, LEDs or pcLEDs located in central portions of an array may be smaller than those located in peripheral portions of the array.

In an array of pcLEDs, all pcLEDs may be configured to emit essentially the same spectrum of light. Alternatively, a pcLED array may be a multicolor array in which different pcLEDs in the array may be configured to emit different spectrums (colors) of light by employing different phosphor compositions. Similarly, in an array of direct emitting LEDs (i.e., not wavelength converted by phosphors) all LEDs in the array may be configured to emit essentially the same spectrum of light, or the array may be a multicolor array comprising LEDs configured to emit different colors of light.

The individual LEDs or pcLEDs in an array may be individually operable (addressable) and/or may be operable as part of a group or subset of (e.g., adjacent) LEDs or pcLEDs in the array.

An array of LEDs or pcLEDs, or portions of such an array, may be formed as a segmented monolithic structure in which individual LEDs or pcLEDs are electrically isolated from each other by trenches and/or insulating material, but the electrically isolated segments remain physically connected to each other by portions of the semiconductor structure.

An LED or pcLED array may therefore be or comprise a monolithic multicolor matrix of individually operable LED or pcLED light emitters. The LEDs or pcLEDs in the monolithic array may for example be microLEDs as described above.

A single individually operable LED or pcLED or a group of adjacent such LEDs or pcLEDs may correspond to a single pixel (picture element) in a display. For example, a group of three individually operable adjacent LEDs or pcLEDs comprising a red emitter, a blue emitter, and a green emitter may correspond to a single color-tunable pixel in a display.

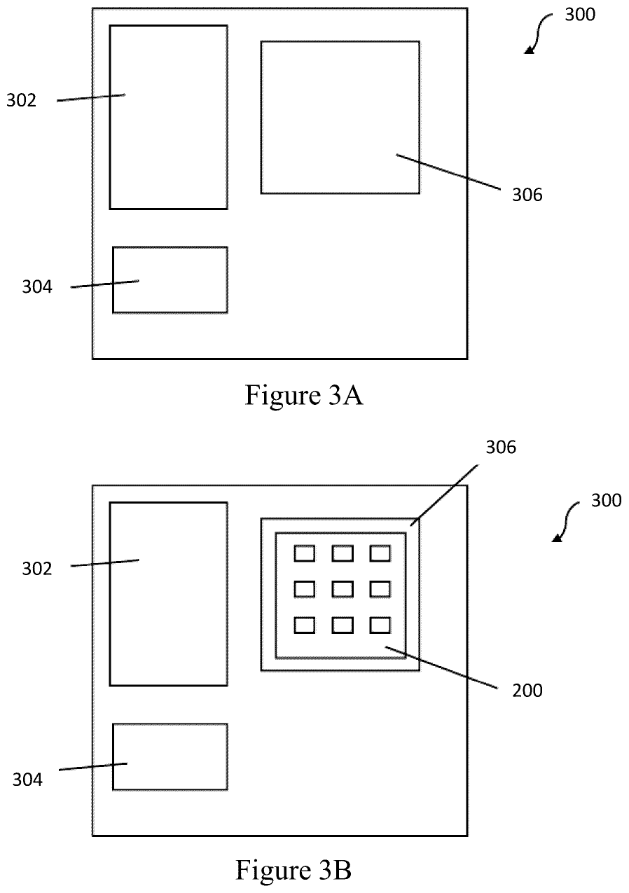

As shown in FIGS. 3A-3B, an LED or pcLED array 200 may be mounted on an electronics board 300 comprising a power and control module 302, a sensor module 304, and an attach region 306. Power and control module 302 may receive power and control signals from external sources and signals from sensor module 304, based on which power and control module 302 controls operation of the LEDs/pcLEDs. Sensor module 304 may receive signals from any suitable sensors, for example from temperature or light sensors. Alternatively, array 200 may be mounted on a separate board (not shown) from the power and control module and the sensor module.

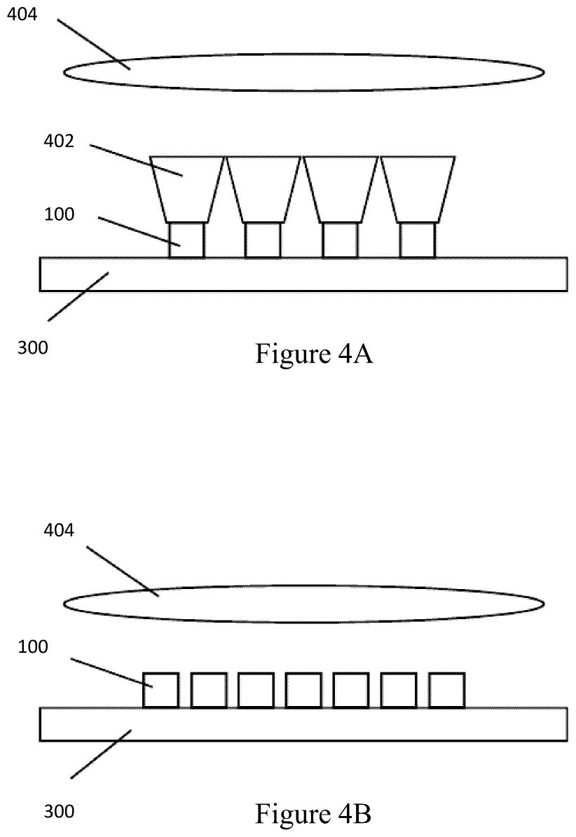

Individual LEDs or pcLEDs may optionally incorporate or be arranged in combination with a lens or other optical element located adjacent to or disposed on the phosphor layer. Such an optical clement, not shown in the figures, may be referred to as a “primary optical element”. In addition, as shown in FIGS. 4A-4B an array 200 (for example, mounted on an electronics board 300) may be arranged in combination with secondary optical elements such as waveguides, lenses, or both for use in an intended application. In FIG. 4A, light emitted by pcLEDs 100 is collected by waveguides 402 and directed to projection lens 404. Projection lens 404 may be a Fresnel lens, for example. This arrangement may be suitable for use, for example, in automobile headlights. In FIG. 4B, light emitted by pcLEDs 100 is collected directly by projection lens 404 without use of intervening waveguides. This arrangement may be particularly suitable when LEDs or pcLEDs can be spaced sufficiently close to each other and may also be used in automobile headlights as well as in camera flash applications. A microLED display application may use similar optical arrangements to those depicted in FIGS. 4A-4B, for example.

In another example arrangement, a central block of LEDs or pcLEDs in an array may be associated with a single common (shared) optic, and edge LEDs or pcLEDs located in the array at the periphery of the central bloc are each associated with a corresponding individual optic.

Generally, any suitable arrangement of optical elements may be used in combination with the LED and pcLED arrays described herein, depending on the desired application.

LED and pcLED arrays as described herein may be useful for applications requiring or benefiting from fine-grained intensity, spatial, and temporal control of light distribution. These applications may include, but are not limited to, precise special patterning of emitted light from individual LEDs or pcLEDs or from groups (e.g., blocks) of LEDs or pcLEDs. Depending on the application, emitted light may be spectrally distinct, adaptive over time, and/or environmentally responsive. Such arrays may provide pre-programmed light distribution in various intensity, spatial, or temporal patterns. The emitted light may be based at least in part on received sensor data and may be used for optical wireless communications. Associated electronics and optics may be distinct at an individual LED/pcLED, group, or device level.

An array of independently operable LEDs or pcLEDs may be used in combination with a lens, lens system, or other optic or optical system (e.g., as described above) to provide illumination that is adaptable for a particular purpose. For example, in operation such an adaptive lighting system may provide illumination that varies by color and/or intensity across an illuminated scene or object and/or is aimed in a desired direction. Beam focus or steering of light emitted by the LED or pcLED array can be performed electronically by activating LEDs or pcLEDs in groups of varying size or in sequence, to permit dynamic adjustment of the beam shape and/or direction without moving optics or changing the focus of the lens in the lighting apparatus. A controller can be configured to receive data indicating locations and color characteristics of objects or persons in a scene and based on that information control LEDs or pcLEDs in an array to provide illumination adapted to the scene. Such data can be provided for example by an image sensor, or optical (e.g., laser scanning) or non-optical (e.g., millimeter radar) sensors. Such adaptive illumination is increasingly important for automotive (e.g, adaptive headlights), mobile device camera (e.g., adaptive flash), VR, and AR applications such as those described below.

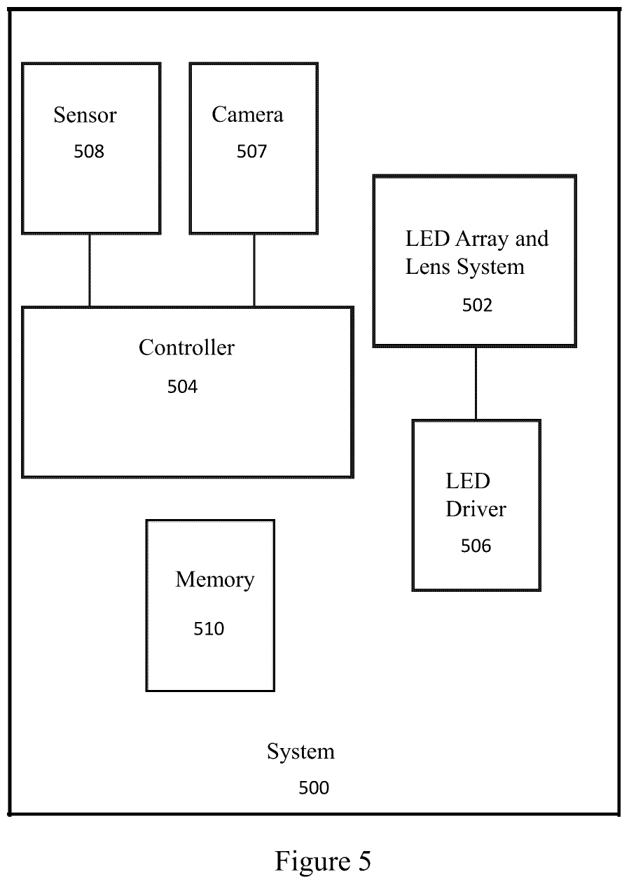

FIG. 5 schematically illustrates an example camera flash system 500 comprising an LED or pcLED array and lens system 502, which may be or comprise an adaptive lighting system as described above in which LEDs or pcLEDs in the array may be individually operable. In operation of the camera flash system, illumination from some or all of the LEDs or pcLEDs in array and lens system 502 may be adjusted—deactivated, operated at full intensity, or operated at an intermediate intensity. The array may be a monolithic array, or comprise one or more monolithic arrays, as described above. The array may be a microLED array, as described above.

Flash system 500 also comprises an LED driver 506 that is controlled by a controller 504, such as a microprocessor. Controller 504 may also be coupled to a camera 507 and to sensors 508 and operate in accordance with instructions and profiles stored in memory 510. Camera 507 and LED or pcLED array and lens system 502 may be controlled by controller 504 to, for example, match the illumination provided by system 502 (i.e., the field of view of the illumination system) to the field of view of camera 507, or to otherwise adapt the illumination provided by system 502 to the scene viewed by the camera as described above. Sensors 508 may include, for example, positional sensors (e.g., a gyroscope and/or accelerometer) and/or other sensors that may be used to determine the position and orientation of system 500.

In conjunction with some or all of the elements/devices mentioned above, a converter material may be used to implement luminescence thermometry. Embodiments of the invention include an improved composition for luminescence-based temperature sensing, e.g., a polycrystalline ceramic converter material. The converter materials and/or devices including these converter materials described below may be used for other purposes than luminescence thermometry, such as for use in pressure sensors.

In embodiments of the invention, doping a phosphor material with a rare earth element (e.g., at cation lattice sites) may improve the capabilities of the material. The phosphor material may be ceramic phosphor or phosphor powder. For example, replacing part of the Gadolinium in polycrystalline GdAlO₃:Cr ceramics with a significantly larger and/or a smaller rare earth element can reduce the orthorhombic distortion of the perovskite lattice without reducing or improving conversion efficiency for excitation in the UVA to blue spectral range. Preferred larger and smaller rare earth elements are lanthanum and lutetium, yttrium, and/or ytterbium leading to inventive polycrystalline converter ceramics of composition Gd_{1-x-y}LaₓRE_{y}Al_{1-z}O₃:Cr_{z} (RE=Y, Yb, Lu) with 0<x≤1, 0≤y≤1, 0≤z≤0.01. The described compositions may also show broadened excitation bands of Cr³⁺ which may be beneficial for narrow line width laser excitation of the ceramic converter.

Additions of small amounts of fumed silica (in the 500 weight-ppm range) may be especially beneficial for sinterability and performance of the converter materials. Adding a small excess of alumina in the starting mixture to synthesize the perovskite aluminate ceramic converters may also be beneficial for the performance of the temperature sensors. Even though additional Al₂O₃:Cr (ruby) emission is observed for a higher Al excess due to the formation of additional alumina grains in the ceramic structure, this emission has no negative effect on the sensing properties of such composite ceramics.

The shape of the converter ceramic in the device may be a plate, a disk, a cylinder, or a cup. The converter ceramic may only comprise one active material as defined below or may be a component that combines conversion functions with light guiding functions, thermal conduction functions, and/or mechanical functions.

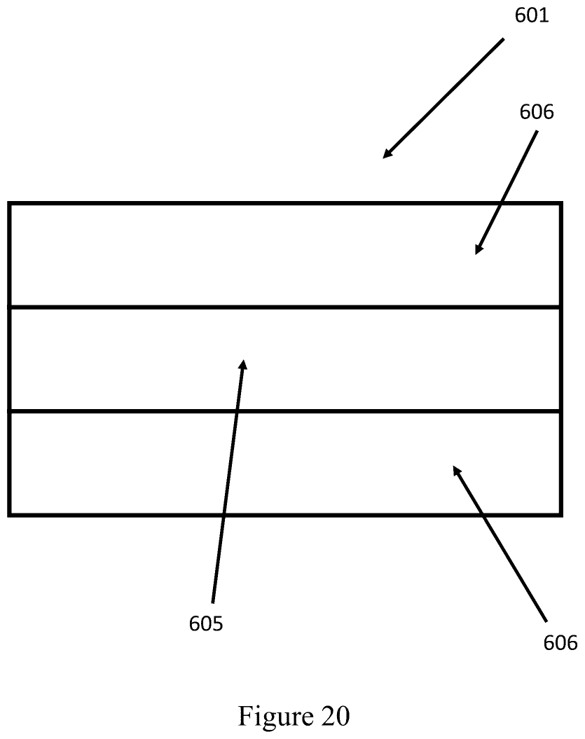

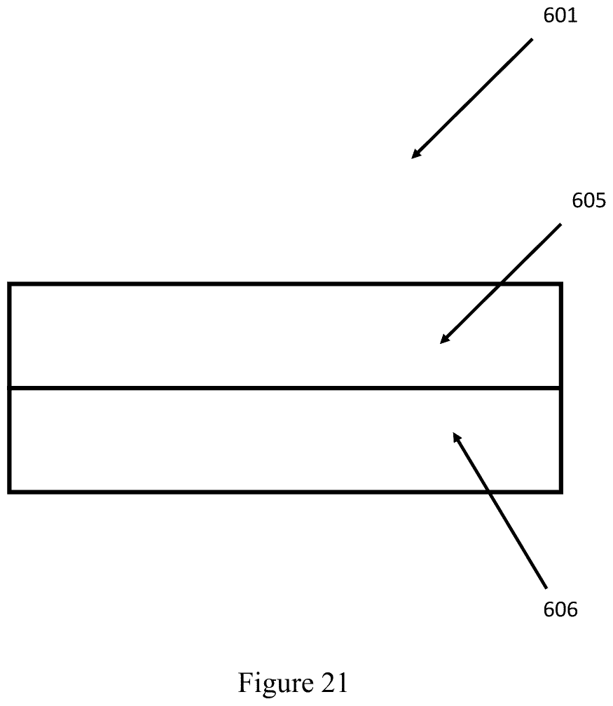

An example shown in FIG. 20 may be a layered converter structure 601 comprising a polycrystalline converter ceramic of composition Gd_{1-x-y}LaₓRE_{y}Al_{1-z}O₃:Cr_{z} (RE=Y, Yb, Lu) with 0<x≤1, 0≤y≤1, 0<z≤0.01 that is sandwiched between two substrates, e.g., transparent material such as sapphire substrates. The interface of the layers may be formed by, e.g., direct sinter-bonding at temperatures above 1600° C., so that the substrate 606 may be in direct contact with the converter material 605 without any adhesive layer in between. Alternatively, as shown in FIG. 21, the converter structure 601 may include only a substrate 606 on one side, e.g., a sapphire substrate.

A series of mixed crystal perovskite converter of composition Gd_{1-x-y}LaₓRE_{y}Al_{1-z}O₃:Cr_{z} (RE=Y, Yb, Lu) with 0<x≤1, 0≤y≤1, 0<z≤0.01 has been synthesized by the following processes described below.

### a) Precursor Material

In embodiments of the invention, a precursor material may be formed by the following process: to avoid the formation of very stable 2^{nd} phases like garnet or hexagonal perovskite compositions a precursor perovskite material of composition LaLuO3 was synthesized by mixing 90.03 g lanthanum oxide (e.g., Treibacher, 4N) and 109.97 g lutetium oxide (e.g., NEO, 4N) with 1 wt % stearic acid by means of planetary ball milling. After firing the mixture at 1400° C. in air atmosphere LaLuO₃ is obtained.

### b) Powder Phosphor

Embodiments of the invention may include a powder phosphor, for example formed with a process using: gadolinium oxide (e.g., Treibacher, 4N), LaLuO₃ precursor prepared according to a), 10.99 g aluminum oxide (e.g., Baikowski, SP-DBM), 0.025 g silicon oxide (e.g., Evonik, OX-50), 0.033 g chromium (III) oxide (e.g., Materion, 3N5), and 0.50 g stearic acid (e.g., Merck, p.a.) was mixed by ball milling according to the weight amounts given in the following table:

TABLE 1

| | Gd₂O₃ | LaLuO₃ |
|---|---|---|
| label | (g) | (g) |
| Comparative | 39.08 | 0.00 |
| example A | | |
| Example 1 | 35.18 | 3.89 |
| Example 2 | 31.28 | 7.79 |
| Example 3 | 27.37 | 11.69 |

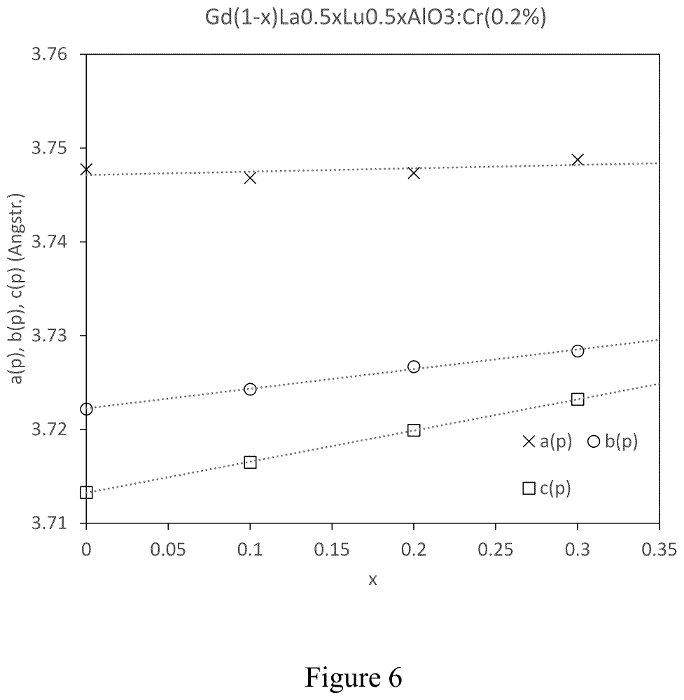

FIG. 6 shows lattice constants of examples 1-3 according to the invention and a comparative example A (for reference) that are all crystallizing in the orthorhombic GdFeO₃ perovskite structure type. FIG. 6 illustrates reduced lattice constants of primitive Perovskite cell with a(p)=a(0)/√2, b(p)=b(0)/2, c(p)=c(0)/√2 (a(0), b(0), c(0) refined with GdFeO3 structure type, Space group Pnma (#62)) of examples A and 1-3. The translation of the lattice constants into lattice constants of the corresponding primitive perovskite lattice cell shows a reduced cell constant length difference with an increase in La and Lu doping. A reduction of the structural anisotropy is beneficial for e.g., the mechanical stability of a polycrystalline ceramic made up from the same composition and crystal structure.

The internal quantum efficiency and centroid wavelength of the examples was measured under excitation of a 440 nm laser diode and barium sulfate powder as a white standard in an integration sphere. The following table shows the obtained values and FIG. 2 shows the emission spectra obtained.

TABLE 2

| Example/composition | Rel IQE (%) | Centroid wavelength (nm) |
|---|---|---|
| Comparative example A/ | 100 | 729.7 |
| GdAl_{0.998}O₃:Cr_{0.002} | | |
| Example 1/ | 122 | 730.7 |
| Gd_{0.9}La_{0.075}Lu_{0.0.75}Al_{0.998}O₃:Cr_{0.002} | | |
| Example 2/Gd_{0.8}La_{0.1}Lu_{0.1}Al_{0.998}O₃:Cr_{0.002} | 122 | 730.8 |
| Example 3/Gd_{0.7}La_{0.15}Lu_{0.15}Al_{0.998}O₃:Cr_{0.002} | 128 | 731.0 |

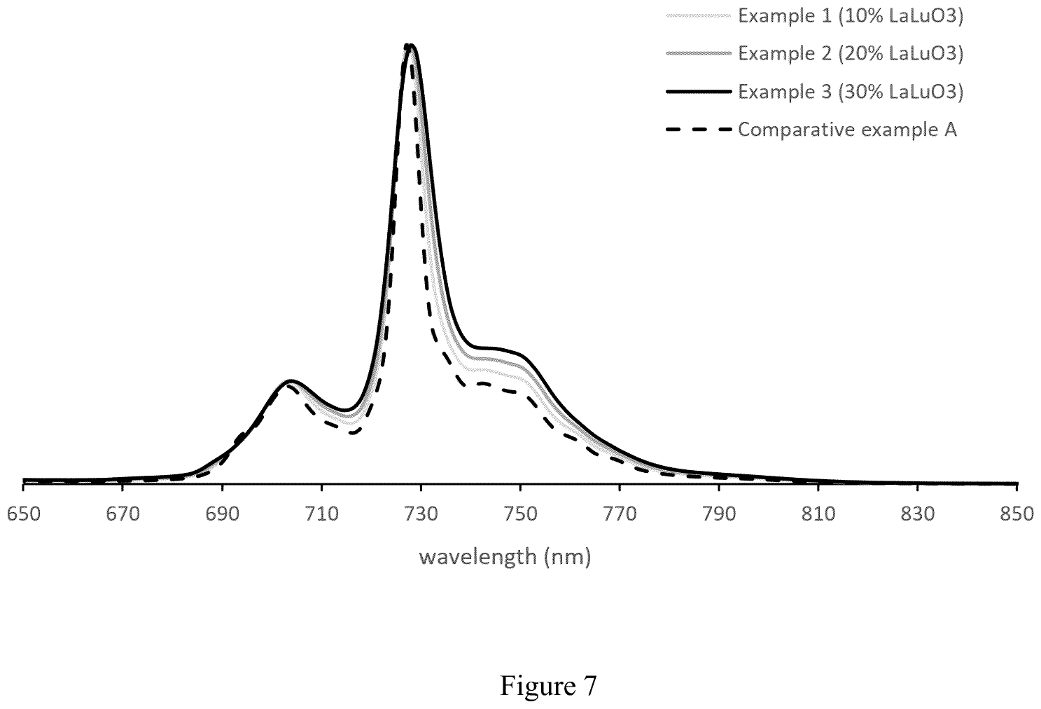

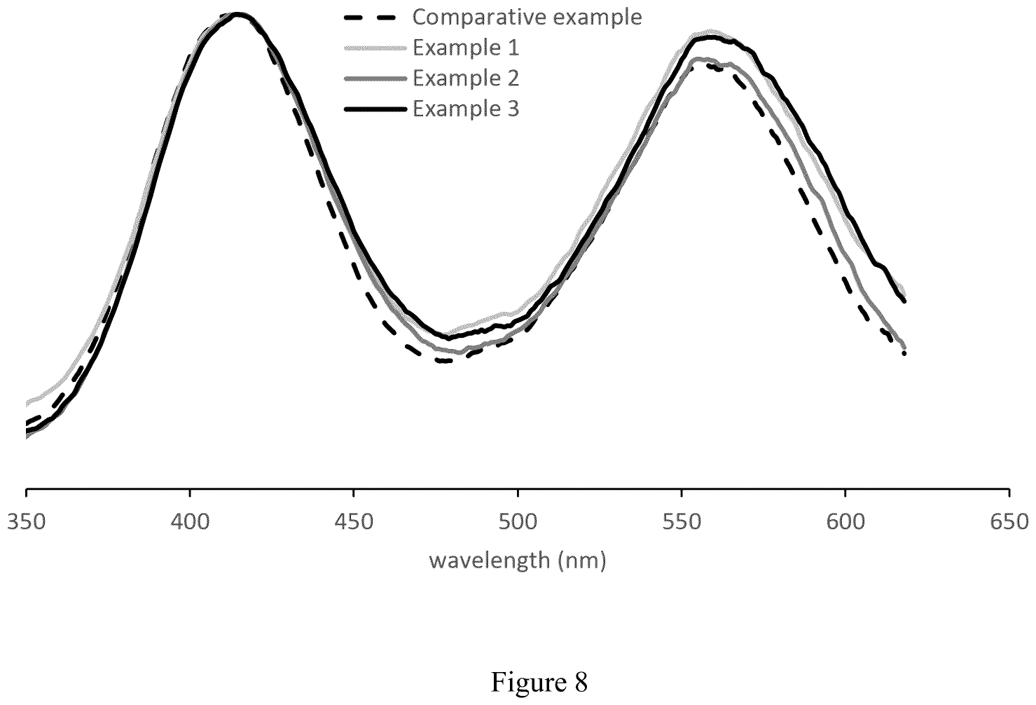

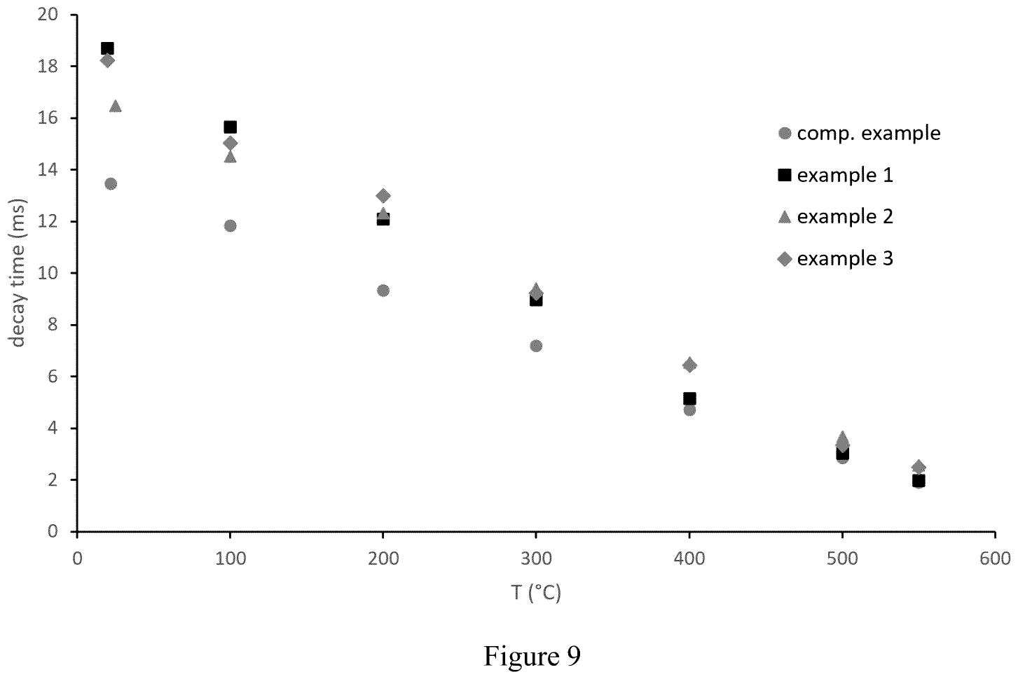

The results show that the incorporation of La and Lu for Gd in GdAlO₃:Cr leads to a red-shift and broadening of the Cr³⁺ room temperature emission and an increase of the internal quantum efficiency. FIG. 7 shows room temperature emission spectra of examples A and 1-3. The emission spectra of examples 1-3 may be in or have a majority in from 670-810 nm, with a peak wavelength between 720-740 nm, for example from 725-730 nm, for example at 728 nm. FIG. 8 shows room temperature excitation spectra for examples A and 1-3. A broadening towards longer wavelengths of the Cr³⁺⁴A₂→²T₂ transition in the violet to blue spectral range can be observed for increasing La and Lu concentrations. FIG. 9 shows single-exponentially fitted decay times of the Cr³⁺⁴T₂→⁴A₂ and ²E→⁴A₂ emission transitions as function of converter material temperature for 415 nm LED excitation. Example 1 shows the steepest change in decay time with T. The LED current was pulsed in the 5 to 20 Hz range and the emission decay traces monitored with a photodetector were fitted mono-exponentially for the 10-60% range of the detector signal maximum. The La and Lu doping leads to an increase of the emission lifetime at lower temperatures while the lifetimes converge at higher temperatures. Example 1 shows the steepest curve of decay time versus temperature which is beneficial for the precision of temperature determination.

In a further example the impact of Yb³⁺ co-doping is demonstrated.

### Example 9: Gd_{0.99}Al_{0.998}O₃:Cr_{0.002}, Yb_{0.01}

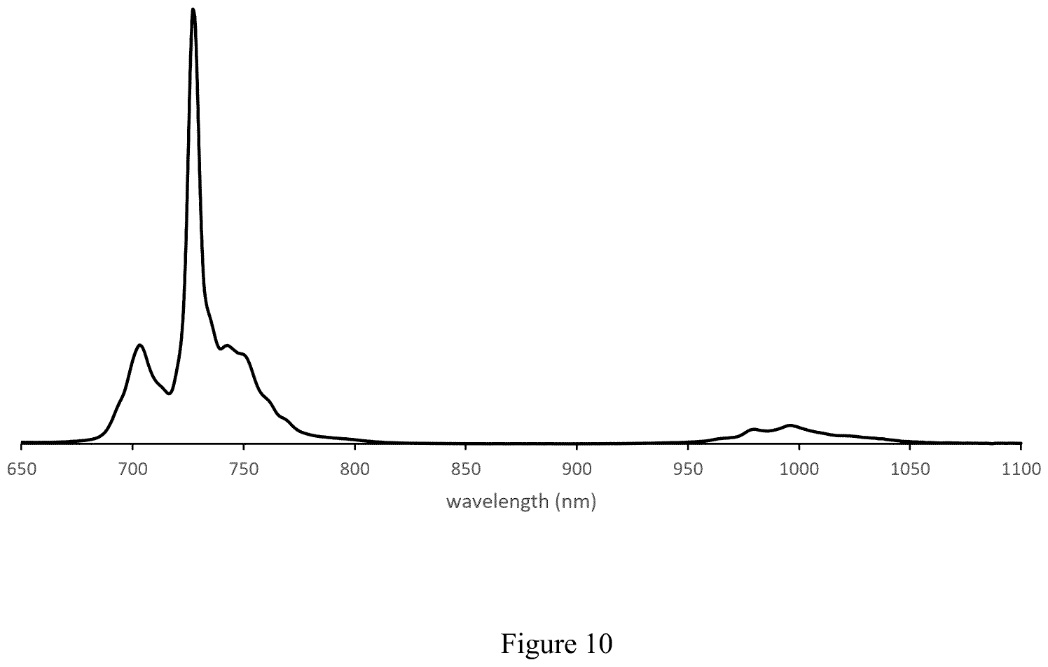

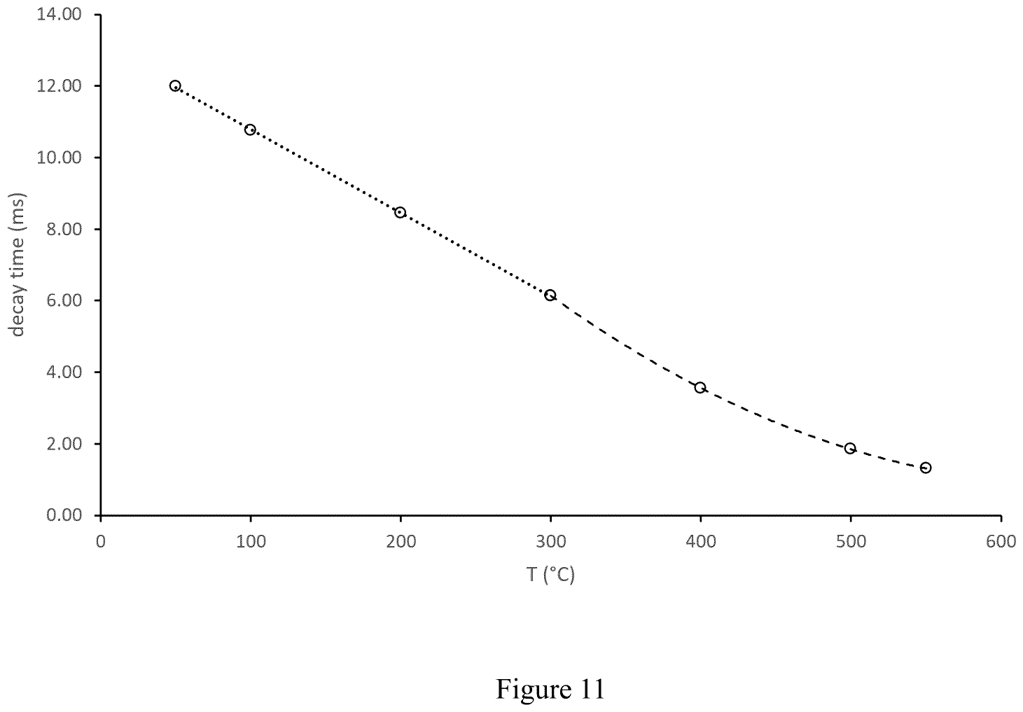

The sample was prepared like comparative example A, except for the amounts of Gd₂O₃ and Yb₂O₃ (e.g., Auer-Remy, 4N) which were 38.69 g and 0.42 g, respectively. FIG. 10 shows the room emission spectrum of example 9 at 440 nm excitation. The Yb³⁺ emission sensitized by Cr³⁺ in the 900-1100 nm wavelength range modifies the luminescence lifetime signal sensed by a silicon photodetector. FIG. 11 shows the mono-exponentially fitted decay time of example 9 as function of the converter temperature. The dotted line is linear fit of data points (open circles), the dashed curve is quadratic fit of data points (open circles). The decay time changes linearly with temperature up to 300° C. which is desired for luminescence decay based temperature determination.

### c) Ceramic Phosphor

Embodiments of the invention include at least one of ceramic phosphors of Examples 4-8 formed according to the processes below. A comparative example B is provided for reference.

### Comparative Example B, Composition GdAl_{0.998}O₃:Cr_{0.002}

259.139 g gadolinium oxide (e.g., Rhodia, 4N), 72.669 g aluminum oxide (e.g., Baikowski, SP-DBM), 0.217 g chromium oxide (e.g., Materion, 3N5) and 0.166 g silica (e.g., Evonik, OX-50) are mixed in 179 g ethanol with a dispersant (e.g., Malialim) by means of ball milling. After addition of a polyvinylbutyral based binder+plasticizer system (e.g., Sckisui) ceramic tapes were casted, dried, stacked and laminated and finally cut into ceramic green bodies. After binder burnout, ceramics were sintered at temperatures in the 1575-1600° C. range to obtain flat ceramic tiles after dicing into 5×5 mm² tiles (thickness 310 μm) for testing.

### Example 4, Composition Gd_{0.75}Al_{0.25}O₃:Cr_{0.002}

183.756 g gadolinium oxide (Rhodia, 4N), 57.718 g lanthanum oxide (e.g., Treibacher, 4N), 68.708 g aluminum oxide (e.g., Baikowski, SP-DBM), 0.205 g chromium oxide (e.g., Materion, 3N5) and 0.155 g silica (e.g., Evonik, OX-50) are mixed in 174 g ethanol with a dispersant (e.g., Malialim) by means of ball milling. After addition of a polyvinylbutyral based binder+plasticizer system (e.g., Sekisui) ceramic tapes were casted, dried, stacked and laminated and finally cut into ceramic green bodies. After binder burnout, ceramics were sintered at temperatures in the 1575° C. range to obtain flat ceramic tiles after dicing into 5×5 mm² tiles (thickness 342 μm) for testing.

### Example 5: Composition Gd_{0.05}La_{0.25}Y_{0.25}Al_{0.998}O₃:Cr_{0.002}

131.991 g gadolinium oxide (Rhodia, 4N), 62.187 g lanthanum oxide (e.g., Treibacher, 4N), 41.099 g yttrium oxide (e.g., Molycorp, 4N), 74.027 g aluminum oxide (e.g., Baikowski, SP-DBM), 0.221 g chromium oxide (e.g., Materion, 3N5) and 0.155 g silica (Evonik, OX-50) are mixed in 171 g ethanol with a dispersant (e.g., Malialim) by means of ball milling. After addition of a polyvinylbutyral based binder+plasticizer system (e.g., Sekisui) ceramic tapes were casted, dried, stacked and laminated and finally cut into ceramic green bodies. After binder burnout, ceramics were sintered at temperatures in the 1575° C. range to obtain flat ceramic tiles after dicing into 5×5 mm² tiles (thickness 325 μm) for testing.

### Example 6: Composition Gd_{0.925}(La_{0.5}Lu_{0.5})_{0.075}Al_{0.998}O₃:Cr_{0.002}

220.27 g gadolinium oxide (e.g., Rhodia, 4N), 38. 80 g LaLuO₃ (prepared as described under a), precursor material), 72.67 g aluminum oxide (e.g., Baikowski, SP-DBM), 0.217 g chromium oxide (e.g., Materion, 3N5) and 0.166 g silica (e.g., Evonik, OX-50) are mixed in 179 g ethanol with a dispersant (e.g., Malialim) by means of ball milling. After addition of a polyvinylbutyral based binder+plasticizer system (e.g., Sekisui) ceramic tapes were casted, dried, stacked and laminated and finally cut into ceramic green bodies. After binder burnout, ceramics were sintered at temperatures in the 1575° C.-1600° C. range to obtain flat ceramic tiles after dicing into 5×5 mm² tiles (thickness 342 μm) for testing.

### Example 7: Composition Gd_{0.85}(La_{0.5}Lu_{0.5})_{0.15}Al_{0.998}O₃:Cr_{0.002}

181.398 g gadolinium oxide (e.g., Rhodia, 4N), 77. 607 g LaLuO₃ (prepared as described under a), precursor material), 72.67 g aluminum oxide (e.g., Baikowski, SP-DBM), 0.217 g chromium oxide (e.g., Materion, 3N5) and 0.166 g silica (e.g., Evonik, OX-50) are mixed in 179 g ethanol with a dispersant (e.g., Malialim) by means of ball milling. After addition of a polyvinylbutyral based binder+plasticizer system (e.g., Sekisui) ceramic tapes were casted, dried, stacked and laminated and finally cut into ceramic green bodies. After binder burnout, ceramics were sintered at temperatures in the 1575° C.-1600° C. range to obtain flat ceramic tiles after dicing into 5×5 mm² tiles (thickness 342 μm) for testing.

### Example 8: Composite Ceramic GdAl_{0.998}O₃:Cr_{0.002}/Al₂O₃:Cr

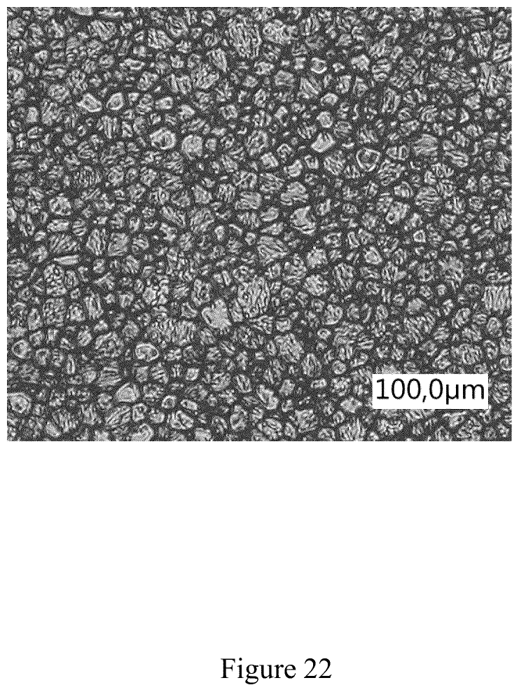

256.329 g gadolinium oxide (Rhodia, 4N), 75.482 g aluminum oxide (e.g., Baikowski, SP-DBM), 0.214 g chromium oxide (e.g., Materion, 3N5) and 0.166 g silica (e.g., Evonik, OX-50) are mixed in 178 g ethanol with a dispersant (e.g., Malialim) by means of ball milling. After addition of a polyvinylbutyral based binder+plasticizer system (e.g., Sekisui) ceramic tapes were casted, dried, stacked and laminated and finally cut into ceramic green bodies. After binder burnout, ceramics were sintered at temperatures in the 1575-1600° C. range to obtain flat ceramic tiles after dicing into 5×5 mm² tiles (thickness 314 μm) for testing. Here, the excess Al leads to Al₂O₃:Cr ceramic grains that are randomly distributed in the ceramic matrix, as shown in FIG. 22, which shows the large perovskite grains and the alumina grains typically only <5 μm in size.

The following table shows the lattice constants (GdFeO₃ structure type, Space group Pnma (#62) and lattice constant ratios as indicators for orthorhombic distortion of the comparative example B and examples 4-8.

TABLE 3

| example | a₀ [Å] | b₀ [Å] | c₀ [Å] | V [Å³] | a₀√2/b₀ | a₀/c₀ |
|---|---|---|---|---|---|---|
| B | 5.3007 | 7.4456 | 5.2528 | 207.31 | 1.0068 | 1.0091 |
| 4 | 5.2974 | 7.4704 | 5.2798 | 208.94 | 1.0028 | 1.0033 |
| 5 | 5.2989 | 7.4835 | 5.2969 | 210.04 | 1.0014 | 1.0004 |
| 6 | 5.2973 | 7.4541 | 5.2598 | 207.69 | 1.0050 | 1.0071 |
| 7 | 5.3013 | 7.4530 | 5.2591 | 207.79 | 1.0059 | 1.0080 |
| 8 | 5.2999 | 7.4459 | 5.2534 | 207.31 | 1.0066 | 1.0089 |

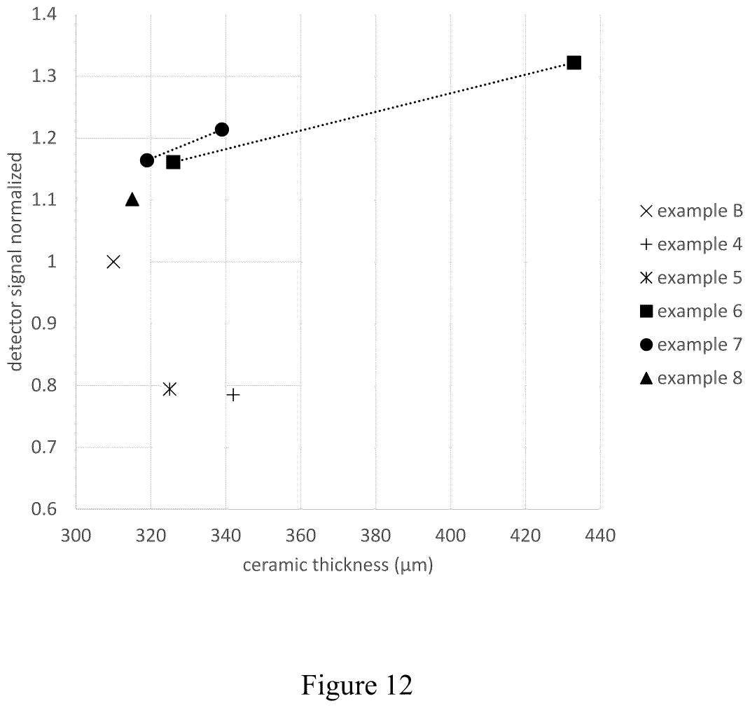

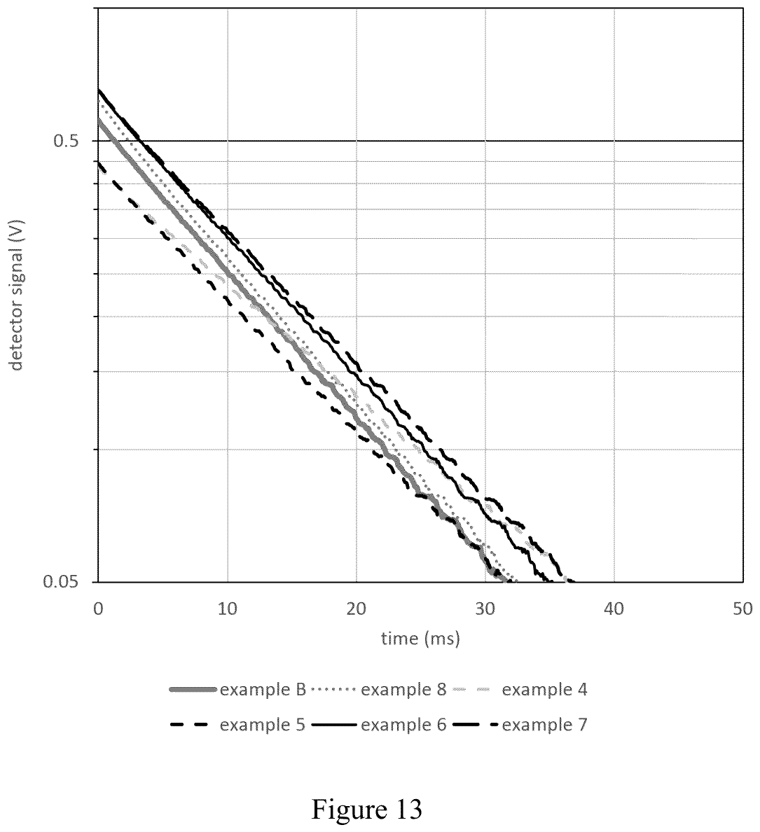

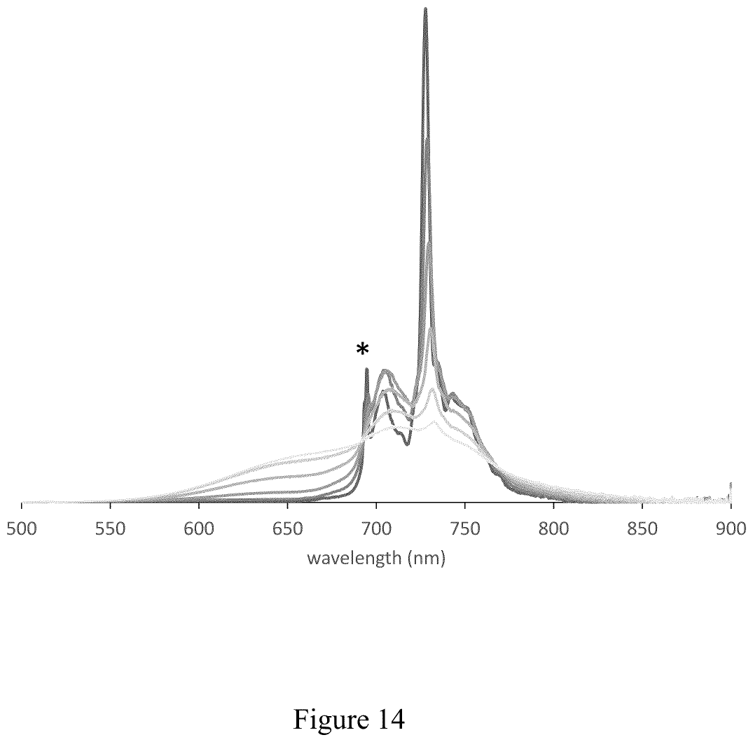

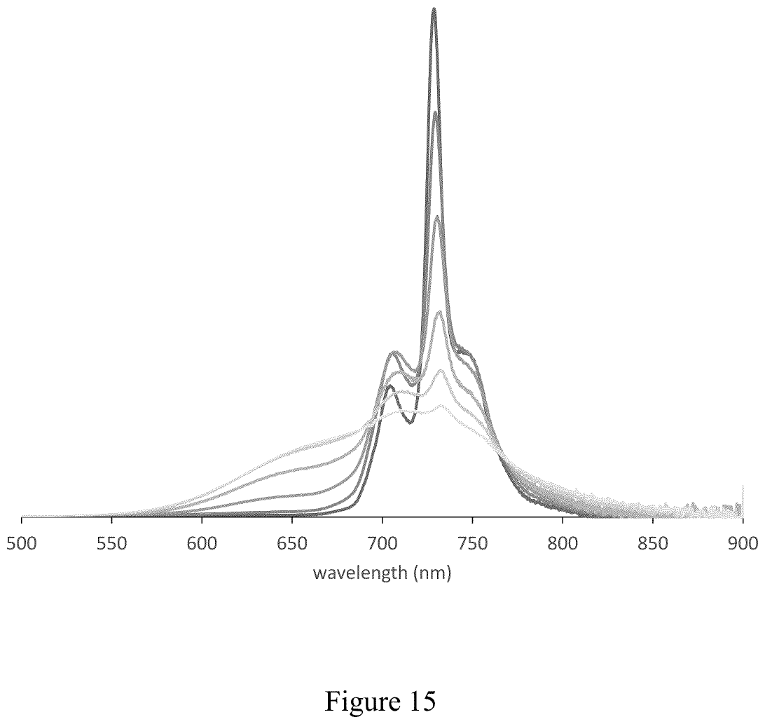

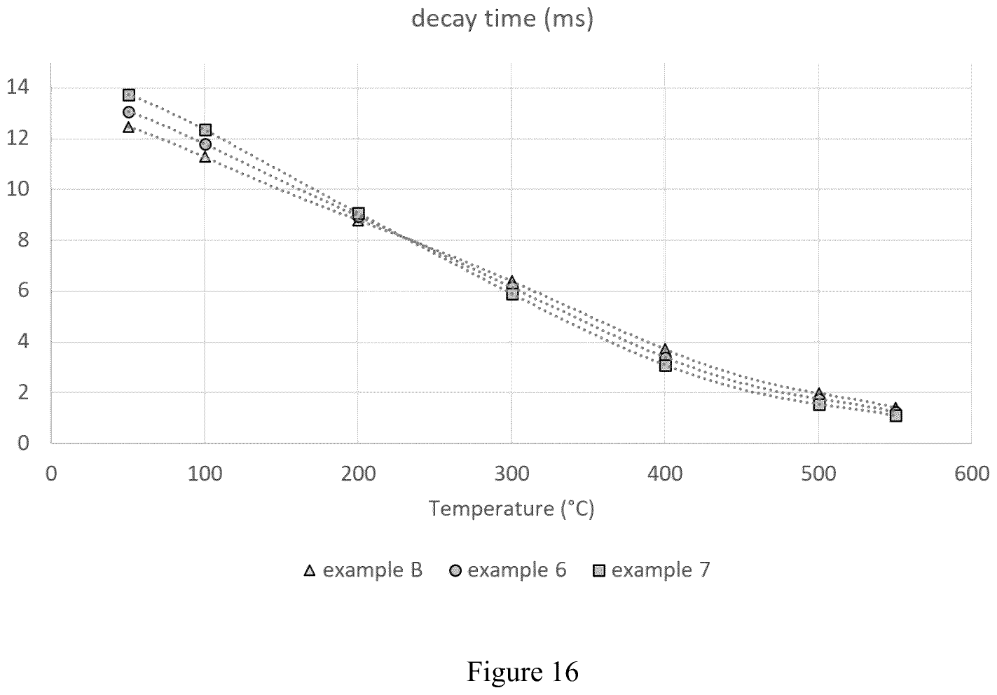

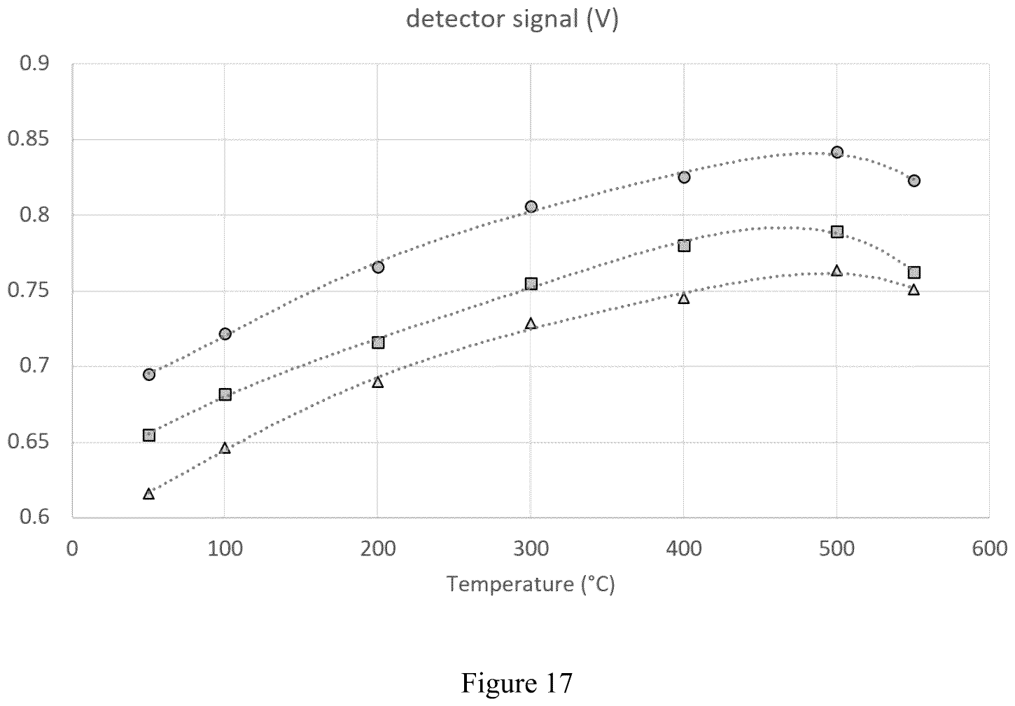

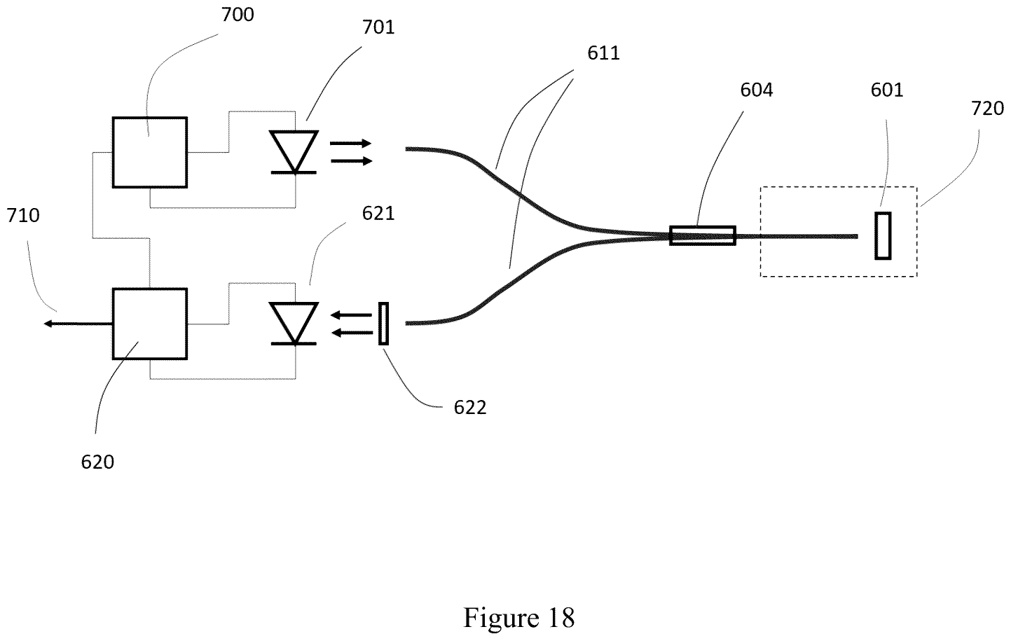

FIG. 12 shows the normalized detector signal at room temperature as function of the ceramic thickness determined with a setup as shown in FIG. 18. The excitation wavelength is 415 nm at 5 Hz. While La and La+Y doping decreases the detector signal, La+Lu doping leads to an increase of the detector signal compared to comparative example B. FIG. 13 shows the corresponding signal decay traces, at the same excitation wavelength and frequency. Examples 6 and 7 show longer decay traces as compared to the other examples. FIG. 14 shows the spectral power distribution of example 8 ceramic emission with the ruby R line emission peak indicated and visible at lower temperatures. The power distribution is shown from 50° C. (dark grey) to 550° C. (light grey) in 100 K steps, and the * indicates Al₂O₃:Cr emission. FIG. 15 shows the spectral power distribution of example 7 ceramic emission, from 50° C. (dark grey) to 550° C. (light grey) in 100 K steps. FIG. 16 shows monoexponentially fitted decay time versus temperature plots for comparative example B and examples 6-7. The excitation is 415 nm (5-20 Hz), while the fitting range is 10-60% of maximum signal. FIG. 17 shows a comparison of the maximal detector signals versus temperature for the same examples and same excitation.

When implemented in a sensor system, the above-described converter materials may be excited remotely by a light emitting diode or laser diode (LD) emitting in and/or with a peak wavelength in the, e.g., 400-450 nm wavelength range. The excitation light may be transported to the converter material by means of a lightguide such as an optical fiber. The light emitted by the converter may also be transported by a lightguide to a detector such as a photodiode, that converts the light into an electrical signal.

For example, the ceramic converter examples may be sintered as plates with a thickness in the 200-400 um range (e.g., the thickness of converter material 605) and applied as luminescence decay sensing elements after e.g. dicing into platelets of 1×1 mm² size in a measurement arrangement as depicted in FIG. 18. FIG. 18 illustrates a device for temperature sensing, In the device, LED/LD driver 700 receives a modulation signal from processing unit 620, a LED/LD 701 connected to the LED/LD driver 700 which emits pulsed light with the same frequency as the modulation signal of a first wavelength range, and optical fibres 611 coupled with a fibre coupler 604 are arranged to receive the pulsed light of the first wavelength range. The converter structure 601 in the temperature probe 720 receives the pulsed light of the first wavelength range from the optical fibres 611 and emits pulsed light of a second wavelength range different from the light of the first wavelength range through a different one of the optical fibres 611. The light passes through a long-pass filter element 622 into a photodetector 621 connected to the processing unit 620 that generates the temperature reading signal 710.

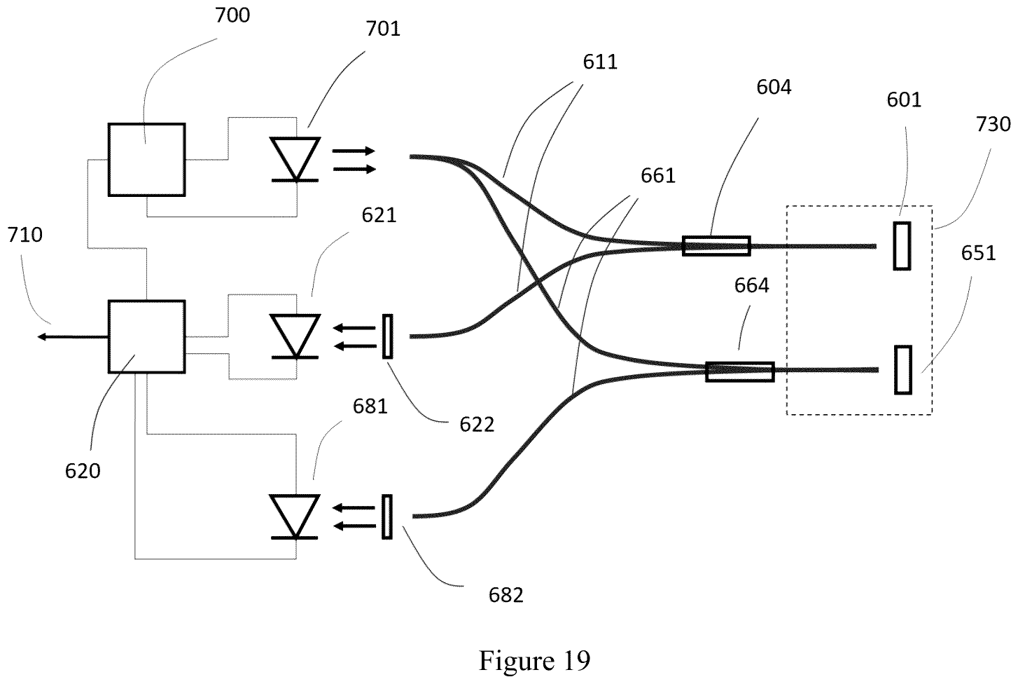

In another embodiment the described phosphor converter examples may be combined with other phosphor converter materials that show different luminescence lifetime kinetics. FIG. 19 illustrates a device for temperature sensing that comprises an additional converter structure 651 in the temperature probe 730, additional optical fibres 611 coupled with a fibre coupler 664, and an additional photodetector 681 with long-pass filter element 682. The additional photodetector 681 may be physically spaced apart from the photodetector 621, and receive light only from additional converter structure 651 while photodetector 621 receives only light from converter structure 601. The additional converter material may have shorter decay times compared to the described examples. Such converters are especially useful to extend the measurement range of the entire measurement device towards very low temperatures. A preferred material class for such additional converters may be the class of Cr³⁺ doped garnet materials (Lu, Y)₃Al₅₋ₓO₁₂:Crₓ (0<x≤0.1). An example may be Lu₃Al_{4.975}O₁₂:Cr_{0.025}. An arrangement for a two channel probe and measurement system is depicted in FIG. 19. The additional converter structure 651 may be arranged on a same plane as the converter structure 601, although this is not required.

The disclosures provided in this specification are intended to illustrate but not necessarily to limit the described implementation. As used herein, the term “implementation” means an implementation that serves to illustrate by way of embodiments but not limitation. The techniques described in the preceding text and figures can be mixed and matched as circumstances demand to produce alternative implementations. It will be apparent to those of ordinary skill in the art that numerous variations, changes, and substitutions of the embodiments described above can be made without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations or equivalents. All such alternatives will be apparent to one skilled in the art in light of this disclosure and are intended to fall within the scope of the appended claims.

What is claimed is:

1. A converter structure comprising:
a substrate;
a luminescent material directly attached to the substrate and comprising Gd_{1-x-y}LaₓRE_{y}Al_{1-z}O₃:Cr_{z} (RE=Y, Yb, Lu) with 0<x≤1, 0≤y≤1, 0<z≤0.01, the luminescent material configured to absorb light of a first wavelength range and emit light of a second wavelength range.

2. The converter structure of claim 1, wherein the luminescent material is a ceramic phosphor.

3. The converter structure of claim 2, wherein the luminescent material comprises one of Gd_{0.75}La_{0.25}Al_{0.998}O₃:Cr_{0.002}, Gd_{0.5}La_{0.25}Y_{0.25}Al_{0.998}O₃:Cr_{0.002}, Gd_{0.925}(La_{0.5}Lu_{0.5})_{0.075}Al_{0.998}O₃:Cr_{0.002}, Gd_{0.85}(La_{0.5}Lu_{0.5})_{0.15}Al_{0.998}O₃:Cr_{0.002}, and GdAl_{0.998}O₃:Cr_{0.002}/Al₂O₃:Cr.

4. The converter structure of claim 1, wherein the luminescent material is a powder phosphor.

5. The converter structure of claim 4, wherein the luminescent material comprises one of Gd_{0.9}La_{0.075}Lu_{0.0.75}Al_{0.998}O₃:Cr_{0.002}, Gd_{0.8}La_{0.1}Lu_{0.1}Al_{0.998}O₃:Cr_{0.002}, Gd_{0.7}La_{0.15}Lu_{0.15}Al_{0.998}O₃:Cr_{0.002}, and Gd_{0.99}Al_{0.998}O₃:Cr_{0.002}.

6. The converter structure of claim 1, wherein x is not equal to zero.

7. The converter structure of claim 1, wherein y is equal to zero.

8. The converter structure of claim 1, wherein y is not equal to zero.

9. The converter structure of claim 1, wherein RE=Y.

10. The converter structure of claim 1, wherein RE=Yb.

11. The converter structure of claim 1, wherein RE=Lu.

12. The converter structure of claim 1, wherein x+y=1.

13. The converter structure of claim 1, further comprising a second substrate directly attached to the luminescent material on an opposite side of the luminescent material from the substrate.

14. The converter structure of claim 1, wherein the substrate is sapphire.

15. The converter structure of claim 1, wherein the first wavelength range has a peak wavelength 400-450 nm.

16. The converter structure of claim 1, wherein the second wavelength range has a peak emission from 720-740 nm.

17. A luminescent sensing device, comprising:
a light device comprising at least one of a light emitting diode (LED) and laser diode (LD);
a luminescent material arranged to receive a first light from the light device and comprising a phosphor converter doped with one or more rare earth elements, the luminescent material configured to emit a second light.

18. The luminescent sensing device of claim 17, wherein the luminescent material comprises Gd_{1-x-y}LaₓRE_{y}Al_{1-z}O₃:Cr_{z} (RE=Y, Yb, Lu).

19. The luminescent sensing device of claim 17, further comprising a photodetector arranged to receive the second light emitted by the luminescent material.

20. The luminescent sensing device of claim 17, further comprising a second luminescent material that does not comprise Gd and arranged to receive the first light of the light device.
